(19) United States
(12) Patent Application Publication
(10) Pub. No.: US 2005/0212097 A1
(43) Pub. Date: Sep. 29, 2005

(54) Charge device model (CDM) electrostatic discharge (ESD) failure rate via capacitive coating

(75) Inventors: Jiaw-Ren Shih, Tsing-Chu (TW); Jian-Hsing Lee, Hsing-chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/811,656

(22) Filed: Mar. 29, 2004

(51) Int. Cl. H01L 23/62

(52) U.S. Cl. 257/666

(57) ABSTRACT

Improving charged device model (CDM) electrostatic discharge (ESD) testing failure rate is disclosed by applying a capacitive coating to an integrated circuit (IC). The IC includes a primary substrate, a number of contacts, and the coating. The substrate has a top surface, a bottom surface, and side surfaces. The contacts are on the top surface, and are connectable to packaging element pins. The capacitive coating is on at least the bottom surface, to make contact with a lead frame intended to secure the substrate to the packaging element. The coating provides a capacitance electrically in series with the capacitance of the IC. The total capacitance during CDM testing is decreased, decreasing the RC constant governing discharge of charge placed on the IC. Discharge occurs more slowly, the discharge current being inversely related to the constant. The maximum discharge current is decreased, allowing the IC to better withstand CDM testing.

### BACKGROUND OF THE INVENTION

Device failure models and test methods define the sensitivity of electronic devices and assemblies that need to be protected from the effects of electrostatic discharge (ESD). Two of the key elements in any successful static-control program are the identification of those items—whether components, assemblies, or finished products—that are sensitive to ESD, and the determination of the level of their sensitivity. The damage done to an electrostatic-discharge-sensitive (ESDS) device by an ESD event depends on the device's ability either to dissipate the energy of the discharge or to withstand the current levels involved. This is known as device ESD sensitivity or ESD susceptibility.

Certain devices may be more readily damaged by discharges occurring within automated equipment, while others may be more prone to damage from handling by personnel. There exist models and test procedures that are used to characterize, determine, and classify the sensitivity of components to ESD. The test procedures are based on the three primary models of ESD events: human body model (HBM), machine model (MM), and charged device model (CDM). While the models employed to perform component testing cannot replicate the full spectrum of all possible ESD events, they have proven successful in reproducing over 95% of all ESD field-failure signatures. The use of standardized test procedures has allowed the industry to: development and measure suitable on-chip protection; make comparison among various devices; and, provide a system of ESD-sensitivity classification to assist in the ESD design and ESD monitoring requirements of the manufacturing and assembly environments.

The human body model (HBM) tests one of the common causes of electrostatic damage, the direct transfer of electrostatic charge through a significant series resistor (+/−1.5 kiloohms) from either the human body or a charged material to the ESDS device. When a person walks across a floor, an electrostatic charge accumulates on his or her body. Simple contact of a finger to the leads of an ESDS device or assembly permits the body to discharge, possibly causing device damage. Thus, the model used to simulate this event is called the human body model (HBM).

The machine model (MM) tests another kind of discharge, similar to the HBM event, which can occur from a charged conductive object such as a metallic tool or fixture. Originating in Japan as a result of attempts to create a worst-case HBM event, this ESD machine model, consists of a 200-picofarad capacitor discharged directly into a component, with no series resistor. As a worst-case HBM, the machine model may be overly severe. However, there are certain real-world situations that this model represents, such as the rapid discharge from a charged board assembly or from the charged cables of an automatic tester.

Finally, the charged device model (CDM) involves the transfer of charge from an ESDS device as an ESD event. A device may, for instance, become charged when sliding down the feeder in an automated assembler. If it then contacts the insertion head or some other conductive surface, a rapid discharge may occur from the device to the metal object. This so-called CDM event can even be more destructive than the HBM event for some devices. Although the duration of the discharge is very short, often less than one nanosecond, the peak current can reach several tens of amperes.

Several test methods have been explored to duplicate the real-world CDM event and replicate the conditions that have been observed in CDM-caused field failures. Efforts in this area are currently focusing on two separate test methods. The first, known as CDM, better simulates the actual charged-device event, while the second addresses devices that are inserted into a socket and then charged and discharged in the same socket. This second method is termed the socketed discharge model, or SDM.

A draft standard for CDM, designated ESD-DS5.3.1-1996, and a standard for CDM, designated ANSI/ESD STM5.3.1-1999, have been released by and are available from the Electrostatic Discharge Association, of Rome, N.Y., which has an Internet world-wide web site at www.esda.org. This test procedure can involve placing the device on a field plate with its leads pointing up, and then charging and discharging the device. FIG. 1 illustrates such a test procedure system 100 for an example device 102. The device 102 is placed on a ground plate 104. The device 102 has a parasitic capacitance 106 and a parasitic inductance 116. The ground plate 104 also has a capacitance 108. A high-voltage source 110, through a charge resistor 112 having a resistance of greater than ten megaohms, charges the device 102. The device 102 is then discharged through a one-ohm measurement resistor 114, as indicated by the discharge event identifier 118. The current through the resistor 114 thus provides a measure of the ESD resistance of the device 102, as to CDM.

The current through the resistor 114 is directly affected by how quickly the charge placed on the example device 102 is able to be discharged to ground. Thus, slower discharge of the charge on the device 102 is desirable, because then the current through the resistor 114 is lower. The discharge time is inversely related to the RC constant of the resistor 114 and the capacitance 106. Lower capacitances and resistances therefore increase the discharge time, and thus reduce the current through the resistor 114. However, decreasing the capacitance of the example device 102 can be difficult to accomplish.

FIG. 2 illustrates another example device 200 that may undergo CDM testing. The example device 200 includes an integrated circuit (IC) 202, situated on a lead frame 204, which secures the IC 202 to a packaging element 206. The IC 202 has a number of contacts 208A, 208B, 208C, . . . , 208N, collectively referred to as the contacts 208. The packaging element 206 has a number pins 210A, 210B, 210C, . . . , 210N, collectively referred to as the pins 210, which provide for external electrical connection to the IC 202 via its contacts 208. As a result, the contacts 208 are correspondingly electrically connected to the pins 210. At least one of the pins 210, such as pin 210C in FIG. 2, is initially charged via connection to a high-voltage source, and then connected to ground 212, as specifically depicted in FIG. 2, to conduct CDM testing of the IC 202.

FIG. 3 shows an electrical schematic 300 of the CDM testing of the example device 200 of FIG. 2. The charge 302 that has been placed on the IC 202 is indicated by the letter Q. The IC 202 has an internal, or parasitic, capacitance 304, as well as an internal, or parasitic, resistance 306. As indicated by the arrow 308, the charge 302 is discharged through the internal capacitance 304 and the internal resistance 306, to the pin 210C of the packaging element 206, and to ground 212. As before, slower discharge of the charge on the IC 202 is desirable, because then the current discharging the charge 302 to ground 212 is lower. The discharge time is again inversely related to the RC constant of resistance 306 and the capacitance 304. Lower capacitances and resistances thus increase the discharge time, and thus reduce the discharge current of the charge 302 on the device 200 to ground 212. However, decreasing the capacitance of the example device 200 can be difficult to accomplish.

For these reasons, as well as other reasons, there is a need for the present invention.

### SUMMARY OF THE INVENTION

The invention relates to an improved charged device model (CDM) electrostatic discharge (ESD) failure rate, during CDM ESD testing, by applying a capacitive coating to an integrated circuit (IC). An IC of the invention includes a primary substrate, a number of contacts, and a capacitive coating. The primary substrate has a top surface, a bottom surface, and a number of side surfaces. The contacts are on the top surface of the primary substrate, and are connectable to pins of a packaging element. The capacitive coating is on at least the bottom surface of the primary substrate, to make contact with a lead frame intended to secure the primary substrate to the packaging element.

An electronic device of the invention includes a packaging element, an IC, a number of contacts, a capacitive coating, and a lead frame. The packaging element has a number of pins to externally connect the electronic device. The IC has a top surface, a bottom surface, and a number of side surfaces. The contacts are on the top surface of the IC, and are connected to the pins of the packaging element. The capacitive coating is at least on the bottom surface of the IC. The lead frame is to secure the IC to the packaging element, where the capacitive coating is sandwiched between the IC and the lead frame.

A method of the invention first coats at least a bottom surface of an IC with a capacitive dielectric having a low k value. Contacts on the top surface of the IC are connected to corresponding pins of a packaging element. The bottom surface of the IC, including the capacitive dielectric, is secured to a lead frame. The lead frame is then secured to the packaging element, such that the capacitive dielectric is sandwiched between the IC and the lead frame. The method may conclude by performing ESD testing on the IC, such as by performing CMD testing on the IC.

Embodiments of the invention provide for advantages over the prior art. The capacitive coating provides a capacitance that is electrically in series with the internal, or parasitic, capacitance of the IC itself, such as of the primary substrate itself. Therefore, the total capacitance during CDM ESD testing is decreased, decreasing the RC constant that governs discharge of a charge placed on the IC during CDM ESD testing. As a result, discharge occurs more slowly, as the discharge current is related to the RC constant. The maximum discharge current at any given time thus is decreased as well. This allows the IC, and the electronic device of which it is a part, to better withstand CDM ESD testing, improving the CDM ESD failure rate.

Still other advantages, aspects, and embodiments of the invention will become apparent by reading the detailed description that follows, and by referring to the accompanying drawings.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is a diagram of a system depicting one way of how charged device model (CDM) electrostatic discharge (ESD) testing can be accomplished within the prior art.

FIG. 2 is a diagram of an example electronic device, including an integrated circuit (IC), which may undergo CDM ESD testing.

FIG. 3 is an electrical schematic showing how the example electronic device of FIG. 2 discharges a charge on its IC when undergoing CDM ESD testing.

FIG. 4 is a diagram of an IC having a capacitive coating on its bottom surface, according to an embodiment of the invention.

FIG. 5 is a diagram of an IC having a capacitive coating on its bottom surface, and extending up to its side surfaces, according to an embodiment of the invention.

FIG. 6 is a diagram of an electronic device having an IC that has a capacitive coating on its bottom surface, according to an embodiment of the invention.

FIG. 7 is an electrical schematic showing how the electronic device of FIG. 6 discharges a charge on its IC when undergoing CDM ESD testing, according to an embodiment of the invention.

FIG. 8 is a graph depicting how the discharge current of the electronic device of FIG. 6, in which the IC of the device has a capacitive coating at least on its bottom surface, is significantly lower than the prior art electronic device of FIG. 2, according to an embodiment of the invention.

FIG. 9 is a flowchart of a method, according to an embodiment of the invention.

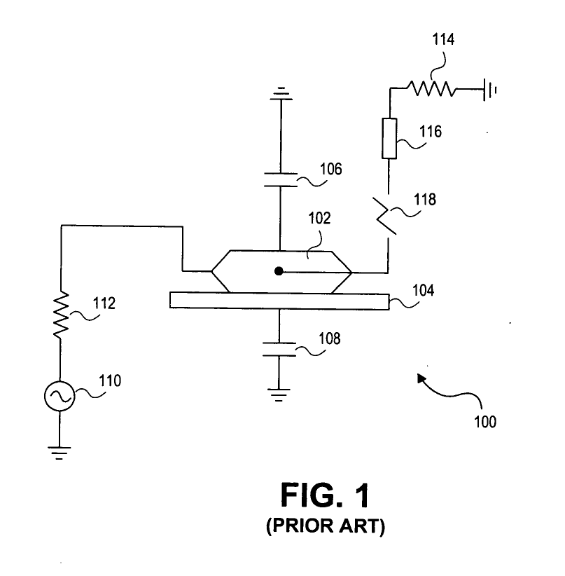

### DETAILED DESCRIPTION OF THE DRAWINGS

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

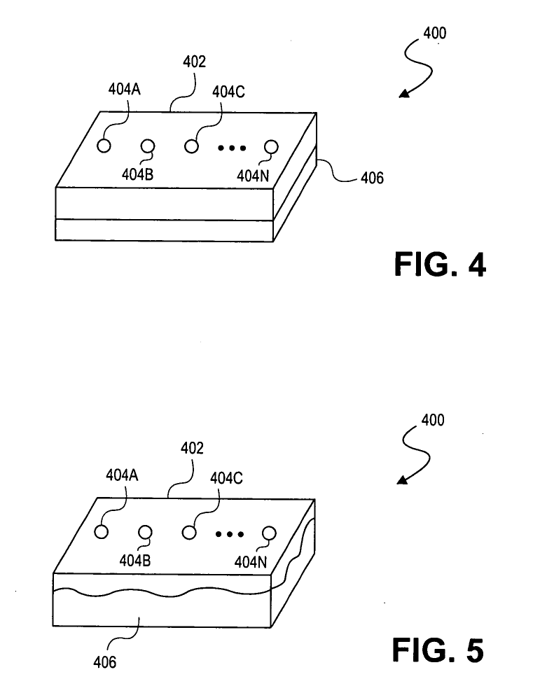

FIG. 4 shows an integrated circuit (IC) 400, according to an embodiment of the invention. The IC 400 includes a primary substrate 402 having contacts 404A, 404B, 404C, . . . , 404N, collectively referred to as the contacts 404, on the top surface of the primary substrate 402. As can be appreciated by those of ordinary skill within the art, the IC 400 can and typically does include other electrical and electronic components, besides those depicted in FIG. 4. The primary substrate 402, and hence the IC 400 itself, also has side surfaces and a bottom surface, besides a top surface. The contacts 404 are connectable to pins of a packaging element. A packaging element is generally a protective container for a semiconductor chip, or IC, that has electrically connectable external leads, or pins.

A capacitive coating 406 has been applied to the bottom surface of the primary substrate 402 of the IC 400 in FIG. 4. The capacitive coating 406 is in one embodiment a capacitive dielectric that has a low k value. The k value of the capacitive dielectric is the dielectric constant of the capacitive coating 406. In general, capacitance is directly proportional to the surface area of the conductive plates to either side of the dielectric, and inversely proportional to the distance separating the two plates. Furthermore, capacitance is proportional to the dielectric constant of the dielectric, or its k value. Therefore, the capacitive coating 406 acts as a capacitive dielectric between the primary substrate 402, where it has one or more conductive portions acting as the first conductive plate, and the material on the other side of the capacitive coating 406, such as a lead frame, as will be described, acting as the second conductive plate. Because the capacitive coating 406 has a low dielectric constant, it serves to provide a low, extra capacitance. In one embodiment, the capacitance provided by the capacitive coating is less than the internal, or parasitic, capacitance of the IC 400 itself. In one embodiment, the thickness of the capacitive coating 406 is between 0.01 millimeters and 1.0 millimeters, such as 0.1 millimeters.

FIG. 5 shows the IC 400, according to another embodiment of the invention. The IC 400 again includes the primary substrate 402 having the contacts 404 on the top surface of the primary substrate 402. The contacts 404 are connectable to pins of a packaging element. The IC 400 also again has a bottom surface and side surfaces, in addition to the top surface on which the contacts 404 are situated.

The capacitive coating 406 has been applied to the bottom surface of the primary substrate 402 of the IC 400 in FIG. 5, and extends up to substantially cover the side surfaces of the primary substrate 402 of the IC 400 as well. Otherwise, the capacitive coating 406 serves the same purpose in FIG. 5 as it does in FIG. 4. FIG. 5 has been included to show that the coating 406 does not have to only be on the bottom surface of the IC 400, and can also extend up to the side surfaces of the IC 400. Therefore, while applying the capacitive coating 406 to the bottom surface of the IC 400, should some of the coating 406 be inadvertently or purposefully applied to the side surfaces of the IC 400, this does not matter, and the effect of the capacitive coating 406 remains the same. Preferably, however, the coating 406 does not extend to the top surface of the IC 400.

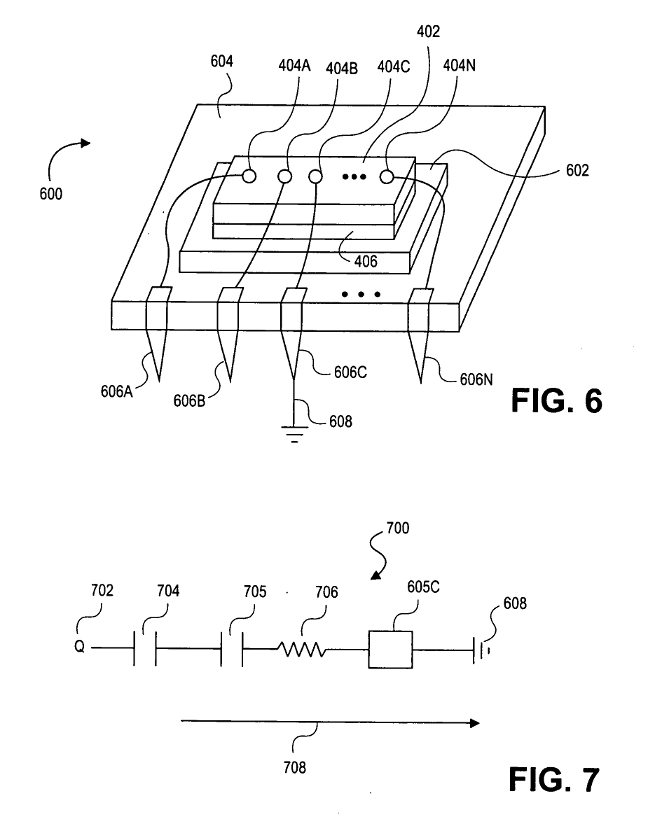

FIG. 6 shows an electronic device 600, according to an embodiment of the invention, which includes the IC 400, and specifically its primary substrate 402, contacts 404, and capacitive coating 406. The IC 400 depicted in FIG. 6 is specifically the IC 400 of the embodiment of FIG. 4. However, this is for example purposes only. In another embodiment of the invention, the IC 400 of the embodiment of FIG. 5 may be employed in conjunction with the electronic device of FIG. 6.

The electronic device 600, besides the IC 400, includes a packaging element 604 having a number of pins 606A, 606B, 606C, . . . , 606N, collectively referred to as the pins 606, and a lead frame 602. As has been described, the packaging element is generally a protective container for a semiconductor chip, such as the IC 400, that has electrically connectable external leads, or pins 606. Although the pins 606 are depicted as only being on the front side of the packaging element 604, this is for illustrative clarity. More typically, the pins 606 will be on more than one side of the packaging element 604, such as the front side and the back side, all the sides of the element 604, and/or on the bottom of the packaging element 604. The contacts 404 are correspondingly connected to the pins 606, enabling the IC 400 to be externally electrically connected, via the pins 606.

The lead frame 602 is to secure the IC 400 to the packaging element 604. As such, the bottom of the IC 400, specifically the capacitive coating 406, makes contact with the lead frame 602 on one side of the lead frame 602, and the other side of the lead frame 602 makes contact with the packaging element 604. In general, the lead frame 602 is a metallic frame containing leads and a based to which the IC 400 is connected. For illustrative clarity only, the lead frame 602 is represented as a rectangular block in FIG. 6. Thus, the electrical connection of the contacts 404 to the pins 606 may be permanently accomplished through the use of the lead frame 602. The lead frame 602 is metallic, as is at least a portion of the bottom surface of the primary substrate 402 of the IC 400. Therefore, it can be seen in FIG. 6 that the capacitive coating 406 is sandwiched between the primary substrate 402 of the IC 400, and the lead frame 602. The lead frame 602 serves as one capacitive plate, and the primary substrate 402 (and hence the IC 400) serve as another capacitive plate, such that the lead frame 602, the primary substrate 402, and the coating 406, serving as a capacitive dielectric, act as a capacitor.

During charged device model (CDM) electrostatic discharge (ESD) testing, a charge is placed on the IC 400, such as on the substrate 402 of the IC 400, by connecting one or more of the pins 606, such as the pin 606C, to a high-voltage source. Thereafter, the high-voltage source is removed, and one or more of the pins 606 are grounded. As depicted in FIG. 6, the pin 606C may be grounded to ground 608. The charge on the IC 400 therefore discharges as discharge current through the pin 606C, and to ground 608. However, the presence of the low capacitance resulting from the capacitive coating 406, in addition to the internal, or parasitic, capacitance of the IC 400 itself, decreases the total capacitance of the discharge path. This decreases the RC constant governing discharge, such that discharge occurs more slowly, reducing the maximum discharge current. As a result, failure rates of IC's, such as the IC 400, that have the capacitive coating 406, are reduced.

FIG. 7 shows an electrical schematic of the discharge path of the IC 400 within the electronic device 600 of FIG. 6 during CDM ESD testing, according to an embodiment of the invention. The charge 702 initially placed on the IC 400 during the beginning of testing is indicated by the letter Q. The capacitance 704 represents the internal, or parasitic, capacitance of the IC 400, such as of the primary substrate 402 of the IC 400. The capacitance 705 represents the capacitance resulting from the capacitive coating 406. That is, the capacitance 705 represents the capacitance resulting from the capacitor effectively made up of the primary substrate 402, the capacitive, or dielectric, coating 406, and the lead frame 602. The resistance 706 represents the internal, or parasitic, capacitance of the IC 400, such as of the primary substrate 402 of the IC 400.

The discharge of the charge 702 on the IC 400 occurs on a path from left to right, as denoted by the arrow 708. The discharge passes through the capacitances 704 and 705 in series with one another, through the resistance 706 in series with the capacitances 704 and 705, through the pin 606C of the electronic device 600, and finally to ground 608. Where the capacitance 704 is represented as the value C, and the resistance 706 is represented as the value R, the discharge constant is represented by the product RC if the capacitive coating 406 is not present. However, where the capacitive coating 406 is present, providing the capacitance 705 that may be represented as the value C′, the total capacitance of the capacitances 704 and 705 in series is represented by the quantity CC′/(C+C′), which is necessarily less than C. This decreases the discharge constant, now represented by the product RCC′/(C+C′). Because discharge time is inversely related to the discharge constant, decreasing the discharge constant slows discharge of the charge 702, reducing the maximum current at any given time over the discharge path to ground 608, as denoted by the arrow 708 in FIG. 7.

That is, adding the capacitive coating 406 results in an effective capacitance 705 being placed in series with the internal, or parasitic, capacitance 704 of the IC 400. The capacitive coating 406 results in the effective capacitance 705 because at least some portion of the substrate 402 of the IC, and the lead frame 602, act as conductive plates to the capacitive coating 406, which serves as the dielectric. Adding the capacitance 705 in series with the capacitance 704 reduces the overall capacitance within the discharge path of the charge 702 to ground 608. This decreases the discharge constant, which increases discharge time, and reduces the maximum current through the discharge path to ground 608, as denoted by the arrow 708 in FIG. 7. Reducing the maximum discharge current means that the IC 400 is better able to withstand CDM ESD testing.

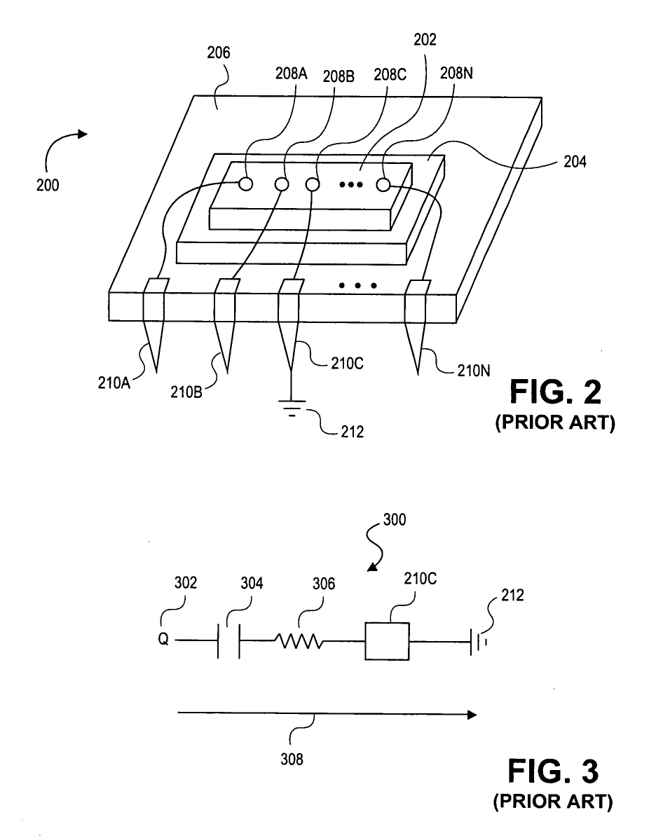

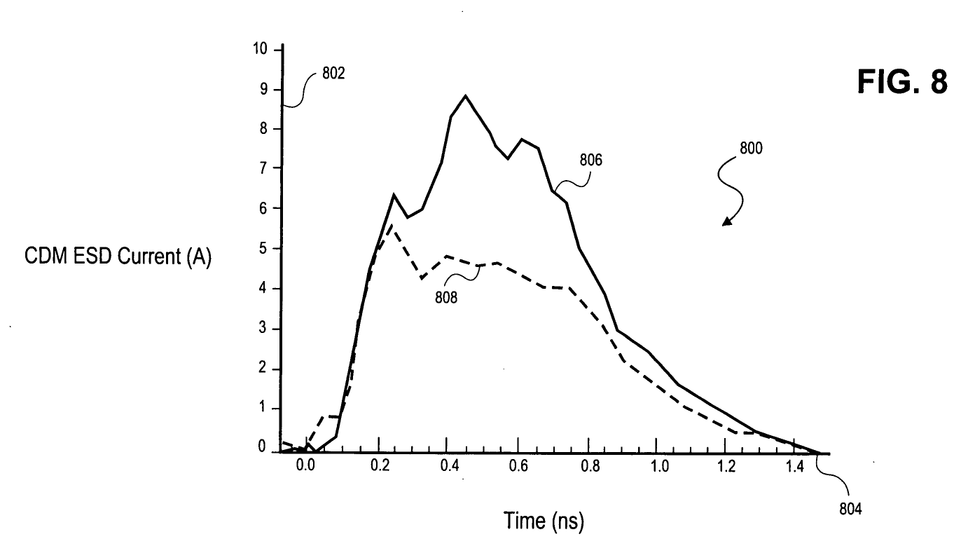

FIG. 8 shows a graph 800 that depicts the significant reduction in the maximum discharge current in the electronic device 600 having the IC 400 with a capacitive coating 406, according to an embodiment of the invention. The graph 800 has a y-axis 802 that denotes discharge, or CDM ESD, current in amps, as a function of time in nanoseconds on the x-axis 804 of the graph 800. The solid line 806 depicts CDM ESD testing of the prior art electronic device 200 of FIG. 2, in which no capacitive coating is applied to the bottom of the IC 202 of FIG. 2. By comparison, the dotted line 808 depicts CDM ESD testing of the electronic device 600 of FIG. 6, in which there is the capacitive coating 406 applied to the bottom of the IC 400. As can be seen from the graph 800, the discharge current is significantly lowered by including the capacitive coating 406 on the bottom of the IC 400. This reduction in the discharge current means that the IC 400 is better able to withstand CDM ESD testing, as compared to the IC 202 of FIG. 2.

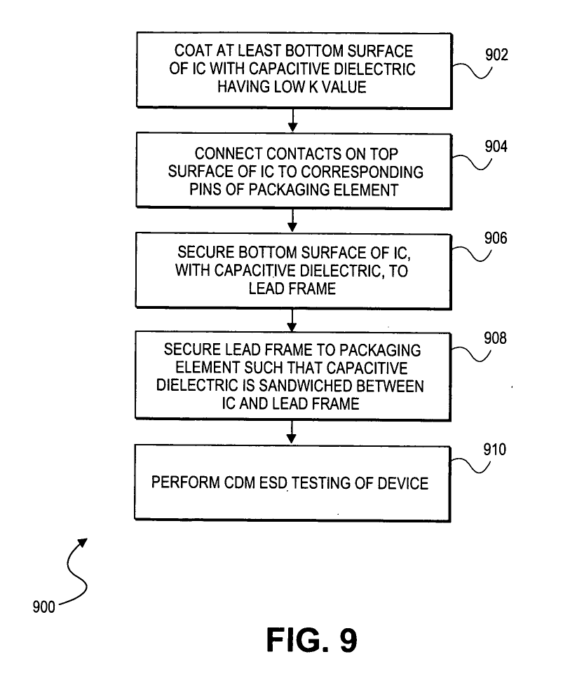

FIG. 9 shows a method 900, according to an embodiment of the invention. The method 900 may be performed in conjunction with the electronic device 600 and/or the IC 400 of either FIG. 4 or FIG. 5. First, at least the bottom surface of an IC is coated with a capacitive dielectric having a low k value (902). The IC may be the IC 400 of FIG. 4 or FIG. 5, where the capacitive dielectric may be the capacitive coating 406 having a low k value, or dielectric constant. For instance, the bottom surface of the IC may be coated with the capacitive dielectric, and optionally one or more of the side surfaces may be at least partially coated with the capacitive dielectric.

Next, the contacts on the top surface of the IC are connected electrically to corresponding pins of a packaging element (904). The contacts may be the contacts 404 of FIGS. 4, 5, and/or 6. The packaging element may be the packaging element 604 of FIG. 6, whereas the pins of the packaging element may be the pins 606 of FIG. 6. The packaging element ultimately encapsulates the IC, so that it is protected in a way that allows for it to be used, by electrical connection of the pins of the packaging element to the contacts of the IC.

The bottom surface of the IC, with its capacitive dielectric, is then secured to a lead frame (906), and the lead frame is secured to the packaging element, such that the capacitive dielectric is sandwiched between the IC and the lead frame (908). The lead frame may be the lead frame 602 of FIG. 6. The lead frame may be that which ultimately allows the contacts of the IC to be electrically connected to the pins of the packaging element, where the IC is permanently encapsulated within the packaging element. The lead frame is metallic, and thus conductive, and acts as one capacitive plate of a capacitor, where at least some portions of the bottom of the IC are conductive and act as another capacitive plate of the capacitor, such that the capacitive dielectric serves as the dielectric of the capacitor. This effective capacitance is electrically in series with the internal, or parasitic, capacitance of the IC.

Finally, CDM ESD testing of the resulting electronic device may be performed (910). As has been described, the addition of the capacitive dielectric coating to the bottom surface of the IC reduces the total capacitance within the discharge path of the charge stored on the IC during CDM ESD testing. This reduces the RC, or discharge constant, increasing the time it takes for the charge to discharge to ground. Thus, the failure rate of the IC during CDM ESD testing is improved, because the IC is less likely to fail, as can be appreciated by those of ordinary skill within the art.

It is noted that, although specific embodiments have been illustrated and described herein, it will be appreciated by those of ordinary skill in the art that any arrangement is calculated to achieve the same purpose may be substituted for the specific embodiments shown. This application is intended to cover any adaptations or variations of the present invention. Therefore, it is manifestly intended that this invention be limited only by the claims and equivalents thereof.

1. An integrated circuit (IC) comprising:
a primary substrate having a top surface, a bottom surface, and a plurality of side surfaces;
a plurality of contacts on the top surface of the primary substrate connectable to pins of a packaging element; and,
a capacitive coating on at least the bottom surface of the primary substrate to make contact with a lead frame intended to secure the primary substrate to the packaging element.

2. The IC of claim 1, wherein the capacitive coating has a capacitance that is lower than an internal capacitance of the IC.

3. The IC of claim 1, wherein the capacitive coating extends from the bottom surface to the plurality of side surfaces of the primary substrate.

4. The IC of claim 1, wherein the capacitive coating is a capacitive dielectric.

5. The IC of claim 4, wherein the capacitive dielectric has a low k value.

6. The IC of claim 1, wherein the capacitive coating has a thickness of between 0.01 millimeters and 1.0 millimeters.

7. The IC of claim 1, wherein the capacitive coating has a thickness of substantially 0.1 millimeters.

8. An electronic device comprising:
a packaging element having a number of pins to externally connect the electronic device;
an integrated circuit (IC) having a top surface, a bottom surface, and a plurality of side surfaces;
a plurality of contacts on the top surface of the IC and connected to the pins of the packaging element;
a capacitive coating on at least the bottom surface of the IC; and,
a lead frame to secure the IC to the packaging element, the capacitive coating sandwiched between the IC and the lead frame.

9. The electronic device of claim 8, wherein the capacitive coating has a capacitance that is lower than an internal capacitance of the IC.

10. The electronic device of claim 8, wherein the capacitive coating extends from the bottom surface to the plurality of side surfaces of the IC.

11. The electronic device of claim 8, wherein the capacitive coating is a capacitive dielectric.

12. The electronic device of claim 11, wherein the capacitive dielectric has a low k value.

13. The electronic device of claim 11, wherein the capacitive coating has a thickness of between 0.01 millimeters and 1.0 millimeters.

14. The electronic device of claim 11, wherein the capacitive coating has a thickness of substantially 0.1 millimeters.

15. A method comprising:
coating at least a bottom surface of an integrated circuit (IC) with a capacitive dielectric having a low k value;
connecting a plurality of contacts on a top surface of the IC to corresponding pins of a packaging element; and,
securing the bottom surface of the IC, with the capacitive dielectric, to a lead frame;
securing the lead frame to the packaging element, such that the capacitive dielectric is sandwiched between the IC and the lead frame.

16. The method of claim 15, further comprising performing electrostatic discharge (ESD) testing on the IC.

17. The method of claim 16, wherein performing the ESD testing on the IC comprises performing charged device model (CDM) testing on the IC.

18. The method of claim 15, wherein coating at least the bottom surface of the IC with the capacitive dielectric comprises coating the bottom surface, and at least substantially one or more side surfaces, of the IC with the capacitive dielectric.

19. The method of claim 15, wherein coating at least the bottom surface of the IC with the capacitive dielectric comprises coating at least the bottom surface of the IC with the capacitive dielectric such that the dielectric has a thickness of between 0.1 millimeters and 1.0 millimeters.

20. The method of claim 15, wherein coating at least the bottom surface of the IC with the capacitive dielectric comprises coating at least the bottom surface of the IC with the capacitive dielectric such that the dielectric has a thickness of substantially 0.1 millimeters.
